(19) United States
(12) Patent Application Publication
(10) Pub. No.: US 2024/0282613 A1
(43) Pub. Date: Aug. 22, 2024

(54) EDGE COVERING AND SEMICONDUCTOR MANUFACTURING DEVICE COMPRISING THE SAME

(71) Applicant: SAMSUNG ELECTRONICS CO., LTD., Suwon-Si (KR)

(72) Inventor: Kwang Sik KIM, Suwon-si (KR)

(21) Appl. No.: 18/494,103

(22) Filed: Oct. 25, 2023

(30) Foreign Application Priority Data
Feb. 16, 2023 (KR) 10-2023-0020753
Feb. 28, 2023 (KR) 10-2023-0026990

(51) Int. Cl. H01L 21/683

(52) U.S. Cl. CPC H01L 21/6833; H01L 21/67069

(57) ABSTRACT

There is provided an edge covering having a structure capable of effectively removing polymer. The edge covering includes a lower ring including a first hole, and an upper ring which is installed on the lower ring and includes a second hole that overlaps the first hole, wherein an edge ring is seated on an upper surface of the lower ring, and the upper ring includes a first side wall that faces the second hole and forms a first angle with the upper surface of the lower ring, the first angle being an acute angle.

This application claims priority from Korean Patent Application No. 10-2023-0020753 filed on Feb. 16, 2023, and Korean Patent Application No. 10-2023-0026990 filed on Feb. 28, 2023, in the Korean Intellectual Property Office, and all the benefits accruing therefrom under 35 U.S.C. 119, the contents of which in their entirety are herein incorporated by reference.

### BACKGROUND

### 1. Field of the Invention

The present disclosure relates to an edge covering and a semiconductor manufacturing device including the same.

### 2. Description of the Related Art

As semiconductors become more precise, an improved process of etching a wafer is required. Foreign matter adhering to the wafer during the etching process may cause deterioration of performance.

In particular, a polymer, which may be a by-product of etching the wafer, may be deposited. Unremoved polymer can fall back onto the wafer and impede etching. this may cause defects. As a result, polymer that is not removed during the process of etching the wafer may cause problems in quality of the semiconductor.

### SUMMARY

Aspects of the present disclosure provide an edge covering having a structure capable of effectively removing polymer.

Aspects of the present disclosure also provide a semiconductor manufacturing device including the edge covering having the structure capable of effectively removing polymers.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

According to an aspect of the present disclosure, there is provided an edge covering comprising a lower ring including a first hole, and an upper ring on the lower ring, where the upper ring includes a second hole that overlaps the first hole, wherein an edge ring is seated on an upper surface of the lower ring, and the upper ring includes a first side wall that faces the second hole and forms a first angle with the upper surface of the lower ring, the first angle being an acute angle.

According to another aspect of the present disclosure, there is provided an edge covering comprising a lower ring which includes a first hole having a lower ring inner diameter, and an upper ring which includes a second hole having an upper ring inner diameter, wherein an edge ring is seated on an upper surface of the lower ring, and the upper ring includes a first side wall that faces the second hole and increases in thickness from an inner side to an outer side of the upper ring.

According to still another aspect of the present disclosure, there is provided a semiconductor manufacturing device comprising an edge covering, an edge ring that is seated on an inner side of the edge covering, an electrostatic chuck which faces the inner side of the edge covering and on which a substrate is loadable, and an upper electrode and a lower electrode spaced apart from each other with an electrostatic chuck interposed therebetween, wherein the edge covering includes a lower ring including a first hole, and an upper ring which is installed on the lower ring and includes a second hole that overlaps the first hole, wherein the edge ring is seated on an upper surface of the lower ring, and the upper ring includes a first side wall that faces the second hole and forms a first angle with the upper surface of the lower ring, the first angle being an acute angle.

### BRIEF DESCRIPTION OF DRAWINGS

The above and other aspects and features of the present disclosure will become more apparent by describing in detail some embodiments thereof with reference to the attached drawings, in which:

FIG. 1 is a cross-sectional view of a semiconductor manufacturing device according to some embodiments of the present disclosure;

FIG. 2 is an enlarged view of a portion R1 of FIG. 1;

FIG. 3 is a perspective view of the edge covering 100 according to some embodiments of the disclosure;

FIG. 4 is a cross-sectional view taken along a line A-A of FIG. 3;

FIG. 5 is a cross-sectional view of the edge covering 100 according to some embodiments of the present disclosure;

FIG. 6 is a cross-sectional view of the edge covering 100 according to some embodiments of the present disclosure;

FIG. 7 is a cross-sectional view showing a semiconductor manufacturing device with a wafer seated thereon according to some embodiments of the present disclosure;

FIG. 8 is an enlarged view of a portion R2 of FIG. 7.

### DETAILED DESCRIPTION OF THE EMBODIMENTS

Embodiments of the present disclosure will be described in detail below with reference to the accompanying drawings. The same reference numerals are used for the same components on the drawings, and repeated descriptions thereof will not be provided.

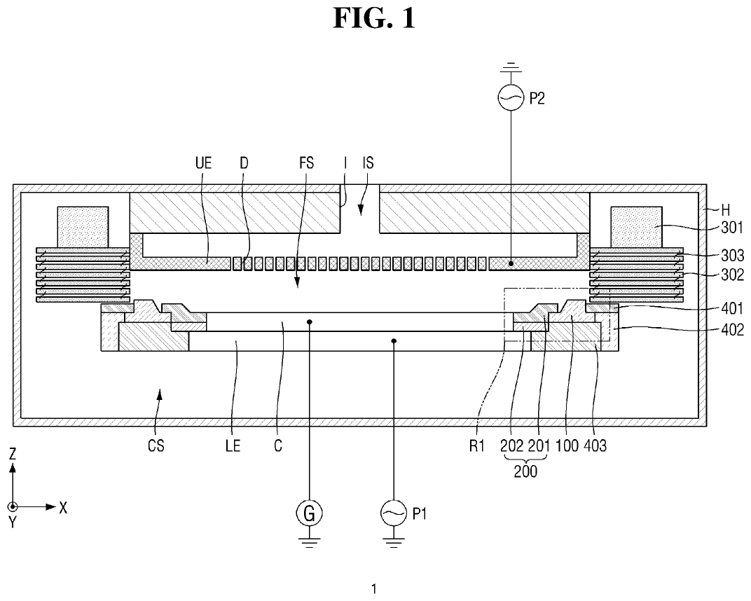

FIG. 1 is a cross-sectional view of a semiconductor manufacturing device according to some embodiments of the present disclosure.

Referring to FIG. 1, a semiconductor manufacturing device may be provided. In this specification, the semiconductor manufacturing device may be a device that performs a process of etching a material such as a wafer W. More specifically, the semiconductor manufacturing device may be a CCP (Capacitively Coupled Plasma) device that performs a dry etching. The CCP device relates to a device that generates plasma after forming an electric field by applying Radio Frequency (RF) power between parallel electrodes facing each other. However, the present disclosure is not limited thereto, and may be a device such as an ICP (Inductively Coupled Plasma) that performs the dry etching. The ICP has an external coil outside the chamber, forms a magnetic field using an applied electric field, and generates a plasma by an electric field induced to the magnetic field.

The semiconductor manufacturing device includes a housing H, a gas injection port I, a gas distribution port D, an upper electrode UE, a lower electrode LE, an electrostatic chuck C, an edge ring 200, an edge covering 100, a ground ring 401, a coupler 403, a ground electrode 402, a generator G, a movement control unit 301, a confinement ring 302, and a ring connection unit 303.

The housing H may define a chamber inner space CS, where the atmosphere within the chamber inner space CS may be controlled. More specifically, the housing H may define an empty inner space that allows the constituent elements of the semiconductor manufacturing device to be disposed. For example, the upper electrode UE, the lower electrode LE, the electrostatic chuck C, the edge ring 200, the edge covering 100, the ground ring 401, the coupler 403, the ground electrode 402, the generator G, and other components of the semiconductor manufacturing device may be disposed in the chamber inner space CS.

The gas injection port I is a structure into which an etching gas used in an etching process is injected. For example, the gas injection port I has a hollow columnar shape, and may inject an etchant from the outside of the housing H into the plasma injection space IS.

The etchant may have a suitable gas combination ratio depending on the material to be etched. For example, when the material to be etched is silicon (Si), an appropriate combination of NF₃, SF₆, CF₄, may be used as the etchant.

In various embodiments, the semiconductor manufacturing device may further include a mass flow controller (MFC). An amount of etchant injected through the gas injection port I may be controlled through a mass flow meter. In the case of gas, considering that each gas can have a different mass and a unit volume of same kind of gas may also change depending on a temperature and a pressure, the mass flow meter may control the mass of the etchant that is injected through the gas injection port I.

The gas distribution ports D may allow passage of the etchant used in the etching process into a plasma formation space FS from a plasma injection space IS. For example, the gas distribution ports D may have a hollow columnar shape, and may allow the etchant injected through the gas injection port I to pass into the plasma formation space FS. The gas distribution ports D may collectively be referred to as a shower head.

The plurality of gas distribution ports may have a structure that penetrates the upper electrode UE. For example, the plurality of gas distribution ports may be passages that connect the plasma injection space IS and the plasma formation space FS.

The upper electrode UE is an electrode for generating plasma together with the lower electrode LE, where the upper electrode UE may be a cathode. The upper electrode UE may be made of, but is not limited to, silicon. The upper electrode UE may be spaced apart from the upper surface of the electrostatic chuck C.

The lower electrode LE is an electrode for generating plasma together with the upper electrode UE, where the lower electrode LE may be an anode. The lower electrode LE may be made of, but is not limited to, silicon. The upper surface of the lower electrode LE may be in contact with the lower surface of the electrostatic chuck C.

The electrostatic chuck C can apply high frequency power to chuck a wafer W during an etching process, and the high frequency power can be removed from the electrostatic chuck C to dechuck the wafer W after the etching process is completed. In addition, the electrostatic chuck C may allow flow of coolant to prevent the temperature of the wafer W from rising due to heat generated during the etching process. Therefore, the temperature of the wafer W may be controlled through the electrostatic chuck C.

In various embodiments, a minute space may exist between the wafer W and the electrostatic chuck C. A gas having excellent thermal conductivity may flow in the space between the wafer W and the electrostatic chuck C, so that the electrostatic chuck C may more effectively control the temperature of the wafer W. For example, the temperature of the wafer W may be effectively lowered by causing a He gas, which has excellent thermal conductivity, to flow between the electrostatic chuck C and the wafer W.

The edge ring 200 may be in the form of a ring and may be formed to surround the periphery of the electrostatic chuck C. The plasma formed in the plasma formation space FS may be concentrated on the upper surface of the wafer W by the edge ring 200, where the plasma may be formed uniformly. The ring shape may be a shape with a circular opening at the center.

In various embodiments, the ring-shaped edge ring 200 may concentrate the plasma generated for the etching process on the wafer W. The edge ring 200 may be made of silicon (Si). Because the main constituent of the wafer W may also be silicon, the plasma may be concentrated on the wafer W when the edge ring 200 is made of silicon (Si). More specifically, the material of the wafer W and the material of the edge ring 200 can be made of the same material, so that the plasma may uniformly etch the wafer W.

The edge ring 200 may be separated into a first edge ring member 201 and a second edge ring member 202, where the first edge ring member 201 may be above the second edge ring member 202. An upper side is called the first edge ring member 201 and a lower side is called the second edge ring member 202 on the basis of a plane passing through a first direction X and a second direction Y intersecting the first direction. For convenience of explanation, although FIG. 1 shows a case where the plane passing through the first direction and the second direction is the same plane as a lower surface of the edge covering 100, the present disclosure is not limited thereto. The first edge ring member 201 may have a different cross-sectional shape than the second edge ring member 202, where the second edge ring member 202 may have a rectangular cross-section.

The plasma can etch the wafer W, but may also unintentionally etch some peripheral constituent elements. For example, the plasma may etch the upper surface of the edge ring 200 where the first edge ring member 201 may be exposed. When etching the upper surface of the edge ring 200, the upper surface of the edge ring 200 may change unevenly. As a result, the edge ring 200 may not play the role of uniformly forming the plasma, where the uneven surface may affect the electric and/or magnetic fields. Maintaining the upper surface of the edge ring 200 uniform in the etching process may maintain a uniform plasma.

Because etching of the edge ring 200 is concentrated on the upper surface of the edge ring 200, the first edge ring member 201 forming the upper surface of the edge ring 200 may be replaced to keep the upper surface of the edge ring 200 uniform in the etching process. Since the first edge ring member 201 may be independently replaced to keep the upper surface of the edge ring 200 uniform without replacing the second edge ring member 202 or the entire edge ring 200 (the first edge ring member 201 and the second edge ring member 202), replacement costs may be reduced. Therefore, separation of the edge ring 200 into the first edge ring member 201 and the second edge ring member 202 may provide an approach for reducing the replacement costs.

Referring to FIG. 1, the lower surface of the first edge ring member 201 and the upper surface of the second edge ring member 202 can be in physical contact with each other. However, when the first edge ring member 201 is lifted in a third direction Z intersecting the first direction and the second direction after being gripped, the first edge ring member 201 can be detached from the upper surface of the second edge ring member 202. Therefore, after etching is performed and the first edge ring member 201 having an uneven upper surface is detached, a new first edge ring member 201 having a uniform upper surface may be put on the upper surface of the second edge ring member 202 to replace the first edge ring member 201. The lower surface of the first edge ring member 201 can be coextensive with the upper surface of the second edge ring member 202 in the X direction.

The edge covering 100 may be in the form of a ring, and may be formed to surround the periphery of the edge ring 200. The second edge ring member 202 may be seated in a recess in the edge covering 100.

The edge covering 100 can be between the edge ring 200 and the ground ring 401 and may electrically insulate the edge ring 200 from the ground ring 401. A coupler 403 may be between the first edge ring member 201 and the ground ring 401. The edge covering 100 may be made up of quartz.

There is a heat conduction difference between the edge ring 200 and the edge covering 100. More specifically, the temperature of edge ring 200 may be relatively higher than the temperature of the edge covering 100. Polymer (P), which is a by-product generated during the etching process, has features in which it is not deposited at a high temperature but is easily deposited at a low temperature. Therefore, a large amount of polymer (P) may be deposited on an interface between the edge ring 200 and the edge covering 100.

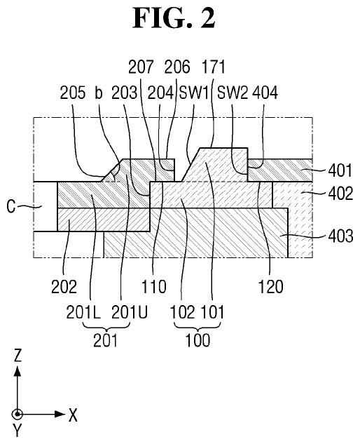

If a large amount of polymer (P) is deposited, the polymer (P) may fall on the wafer W side during the etching process. The polymer (P) which falls on the wafer W side plays a role of impeding etching, and therefore may cause a short circuit or a disconnection. As a result, the performance of the semiconductor may be degraded. A detailed description of the structure of the edge ring 200 for preventing this will be provided below in FIG. 2.

The ground ring 401 may be in the form of a ring and may be formed to surround the periphery of the edge covering 100. The ground ring 401 may be electrically conducting and ground the supplied power. The ground ring 401 may be made up of aluminum (Al).

Although it is not shown, the ground ring 401 may be electrically connected to the upper electrode UE or the electrostatic chuck C. However, the embodiment is not limited thereto. The ground ring 401 may be electrically connected to the upper electrode UE or the electrostatic chuck C via other configurations. In addition, the ground ring can constitute a closed circuit to allow current to flow to the outside of the apparatus, where the ground ring may be connected to other components of the semiconductor manufacturing device.

A coupler 403 may couple a DC voltage generated between the bulk plasma and the electrostatic chuck C. An upper surface of the coupler 403 may be connected to the lower surface of the edge covering 100. More specifically, the output impedance of the generator G and the chamber impedance may be matched to control the coupling voltage between the bulk plasma and the electrostatic chuck C to be large.

The ground electrode 402 may ground the upper electrode UE or the electrostatic chuck C. The upper surface of the ground electrode 402 may be connected to the lower surface of the ground ring 401. The ground electrode 402 may be grounded on the outside to ground the upper electrode UE or the electrostatic chuck C.

The generator G may supply a high frequency power for plasma generation. For the power supply, the generator G may be connected with the electrostatic chuck C through a fin. The generator G may be in the form of surrounding the fin.

The movement control unit 301 is located on the upper surface of the ring connection unit 303 and may be connected to a confinement ring 302, where the ring connection unit 303 can be between the movement control unit 301 and the confinement ring 302. The movement control unit 301 may include a motor. The height of the confinement ring 302 may be adjusted when the motor rotates, and the plasma formation space FS may be sealed through the movement control unit 301.

The confinement ring 302 may be in the form of a ring. The confinement ring 302 may surround the upper electrode UE and/or surround the plasma formation space FS. An inner diameter of the confinement ring can be sufficiently large to fit around the upper electrode UE, and at least a portion of the confinement ring 302 may be in close contact with an outer side of the upper electrode UE. A plurality of confinement rings 302 may be arranged along the third direction, where the confinement rings 302 can be stacked and adjacent confinement rings 302 can be connected to each other through the ring connection unit 303. Therefore, the plasma formation space FS may be sealed when the space between the plurality of confinement rings 302 decreases.

When sealing the plasma formation space FS, the motor of the movement control unit 301 rotates in the first direction (for example, a clockwise direction). All the confinement rings may gradually descend downward by the action of the motor of the movement control unit 301. Because the adjacent confinement rings are connected through the ring connection unit 303, the movement due to the motor of the movement control unit 301 may be transferred to all the confinement rings, where the confinement rings 302 may descend towards he ground ring 401. A portion of the lowermost confinement ring 302 may come into contact with an upper surface of the ground ring 401. After the lowermost confinement ring 302 comes into contact with the ground ring 401, further descent may be blocked by the ground ring 401. Therefore, the confinement ring may not descend any lower. Because the ring connection unit 303 may be a film-like structure that may be expanded and contracted in the third direction, when the confinement ring 302 descends, the ring connection unit 303 can expand simultaneously, while being connected to the adjacent confinement ring. Eventually, the plurality of confinement rings 302 and the ring connection unit 303 may seal the plasma formation space FS.

When the plasma formation space FS is opened, the motor of the movement control unit 301 rotates in the second direction (for example, a counterclockwise direction). All the confinement rings 302 may gradually ascend upward by the motor of the movement control unit 301. Since the adjacent confinement rings 302 are connected through the ring connection unit 303, the movement due to the motor of the movement control unit 301 may be transferred to all the confinement rings 302. In this case, the lowermost confinement ring ascends and may be spaced apart from the ground ring 401. Since the ring connection unit 303 may be a film-like structure that may be expanded and contracted in the third direction, when the confinement ring 302 ascends, the ring connection unit 303 simultaneously contracts, while being connected to the adjacent confinement ring. Eventually, the plurality of confinement rings and the ring connection unit 303 may open the plasma formation space FS. The plasma formation space FS may be fluidly connected passed the confinement ring 302 and ring connection unit 303 to the chamber inner space CS.

In various embodiments, the semiconductor manufacturing device may further include a vacuum pump. The vacuum pump may include a dry pump which may draw gas from an atmospheric pressure to a low vacuum level and a turbo pump which may draw gas to a high vacuum level.

The vacuum pump can be used to draw the gas out of the chamber, but polymer (P), which is by-product, may also partially move in a direction in which the gas is drawn. That is, the polymers (P) existing in the plasma formation space FS may move to the chamber inner space CS.

FIG. 2 is an enlarged view of a portion R1 of FIG. 1.

Referring to FIG. 2, the edge ring 200 may be separated into a first edge ring member 201 and a second edge ring member 202. Also, the first edge ring member 201 may be separated into a ring-shaped upper first edge ring 201U and a ring-shaped lower first edge ring 201L. However, for convenience of explanation, the first edge ring member 201 is separated into the upper first edge ring 201U and the lower first edge ring 201L, and the first edge ring member 201 may be a structure in which the upper first edge ring 201U and the lower first edge ring 201L are two sections of a single structure formed integrally.

The upper first edge ring 201U may include a first edge ring protrusion 204, a first edge ring side wall 205, a first edge ring extension surface 206, and a second edge ring extension surface 207.

The edge ring protrusion 204 may exist outside the upper first edge ring 201U. Although the edge ring protrusion 204 is shown as being vertically contiguous with the upper surface of the lower first edge ring 201L for convenience of explanation, the embodiment is not limited thereto. Since the edge ring protrusion 204 exists at the outermost part of the first edge ring member 201, the edge ring protrusion 204 may have a protruding shape when viewed from the outside.

The edge ring side wall 205 may form a surface of the upper first edge ring 201U. The edge ring side wall 205 may form an edge ring angle b with the upper surface of the lower edge ring 201L. When edge ring angle b changes, the extent to which the edge ring 200 may concentrate the plasma on the wafer W changes. Therefore, the edge ring angle b may be selected to form an optimum angle for concentrating the plasma.

The first edge ring extension surface 206 connects the uppermost end of the edge ring side wall 205 and the uppermost end of the edge ring protrusion 204. Although the first edge ring extension surface 206 is shown as being parallel to the upper surface of the lower first edge ring 201L for convenience of explanation, the embodiment is not limited thereto.

The second edge ring extension surface 207 connects an uppermost end of an edge ring recess surface 203, which will be described below, with the lowermost end of the edge ring protrusion 204. Although the second edge ring extension surface 207 is shown as being parallel to the upper surface of the lower first edge ring 201L for convenience of explanation, the embodiment is not limited thereto. Although the second edge ring extension surface 207 is also shown as being parallel to the first edge ring extension surface 206, the embodiment is not limited thereto.

The lower first edge ring 201L may include an edge ring recess surface 203.

The edge ring recess surface 203 may be outside the lower first edge ring 201L. Although the edge ring recess surface 203 is shown as being vertically connected to the lower surface of lower first edge ring 201L for convenience of explanation, the embodiment is not limited thereto. The edge ring recess surface 203 forms a step between the bottom surface of the lower first edge ring 201L and the second edge ring extension surface 207, such that the edge ring protrusion 204 extends away from the lower first edge ring 201L. Therefore, the edge ring recess surface 203 may have a recessed shape when viewed from the outside.

As a result, the edge ring recess surface 203, the edge ring protrusion 204, and the second edge ring extension surface 207 may have a stepped shape when viewed from the outside.

Referring to FIG. 2 again, the edge ring 200 may be loaded inside the edge covering 100, where the edge covering 100 can support at least a portion of the edge ring 200. A method of loading the edge ring 200 is as follows.

First, the first edge ring member 201 is gripped. The first edge ring member 201 may be gripped by applying a proper pressure to the first edge ring member 201 after any operator puts on gloves. At this time, the gloves may be made of a material that prevents foreign matters from being adsorbed to the first edge ring member 201.

Next, the first edge ring member 201 is put on the upper surface of the second edge ring member 202 to be sandwiched between the inner side of the edge covering 100 and the electrostatic chuck C.

As will be described below, the edge covering 100 has a first loading portion 110. When the first edge ring member 201 is put on the upper surface of the second edge ring member 202 and the first loading portion 110, the first loading portion 110 and the second edge ring extension surface 207 may be in physical contact with each other.

The inner side of the lower ring 102 and the edge ring recess surface 203 may not be separated from each other. Therefore, the generated polymer (P) may not penetrate between the inner side of the lower ring 102 and the edge ring recess surface 203. Also, the first loading portion 110 and the second edge ring extension surface 207 that are in contact with each other may not be separated from each other. Therefore, the generated polymer (P) may not penetrate between the first loading portion 110 and the second edge ring extension surface 207.

Referring to FIG. 2 again, a ground ring 401 may be loaded on the outer side of the edge covering 100. As will be described below, the edge covering 100 has a second loading portion 120. When the ground ring 401 is put on the upper surface of the ground electrode 402 and the second loading portion 120, the second loading portion 120 and at least a part of the lower surface of the ground ring 401 may be in contact with each other. Also, the ground ring protrusion 404 may be in contact with the second side wall SW2.

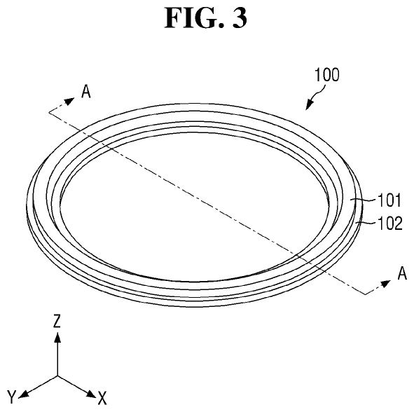

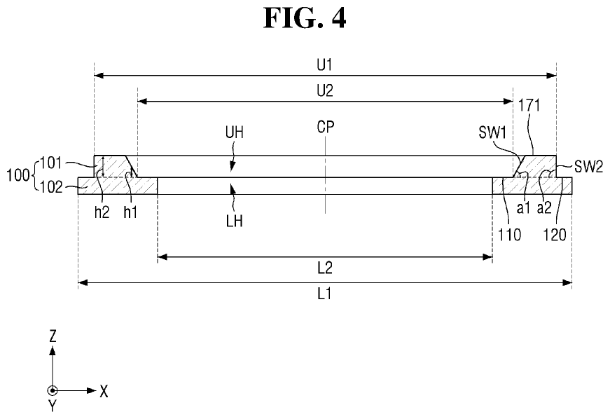

FIG. 3 is a perspective view of the edge covering 100 according to some embodiments of the disclosure. FIG. 4 is a cross-sectional view taken along a line A-A of FIG. 3.

Referring to FIGS. 3 and 4, the edge covering 100 may be separated into an upper ring 101 and a lower ring 102. However, the edge covering 100 is separated into the upper ring 101 and the lower ring 102 for convenience of explanation, and the edge covering 100 may be a structure in which the upper ring 101 and the lower ring 102 are integrally formed.

The lower ring 102 is in the form of a ring and may include a first hole LH. For example, the first hole LH is an empty space, and may have a structure through which a cylinder having the center of the lower ring 102 as a central axis CP penetrates. In this case, an outer diameter of the cylinder of the first hole LH may be an inner diameter L2 of the lower ring.

Since the lower ring 102 is in the form of a ring, the outermost contour of the lower surface of the lower ring 102 may form a circle when the lower ring 102 is flattened in the third direction. In this case, the diameter of the circle may be an outer diameter L1 of the lower ring.

The upper ring 101 is in the form of a ring and may include a second hole UH. For example, the second hole UH is an empty space, and may have a structure through which a truncated cone having the center of the upper ring 101 as a central axis CP penetrates. In this case, among the circles of truncated cone of the second hole UH, there may be a circle positioned on the upper surface side of the lower ring 102, and the diameter of this circle may be the inner diameter U2 of the upper ring.

Since the upper ring 101 is in the form of a ring, when the upper ring 101 is flattened in the third direction, the outermost contour of the upper surface of the upper ring 101 may form a circle. In this case, the diameter of the circle may be the outer diameter U1 of the upper ring.

The first hole LH may overlap the second hole UH. More specifically, the upper surface of the first hole LH may face the lower surface of the second hole UH. The first hole LH and the second hole UH may be centered on the same axis.

The upper ring 101 includes a first side wall SW1, a second side wall SW2, and a first extension surface 171 extending from the first side wall SW1 to the second side wall SW2.

The first side wall SW1 may form a first angle a1 with the upper surface of the lower ring 102, and the first angle a1 may be an acute angle. That is, the thickness h1 of the first side wall SW1 may increase from the inner side to the outer side of the upper ring 101.

In FIG. 4, the first side wall SW1 is shown to linearly increase in thickness from the inner side to the outer side of the upper ring 101. That is, the extent to which the thickness h1 of the first side wall SW1 increases from the inner side to the outer side of the upper ring 101 is constant, and the first side wall SW1 is shown in the form of a straight line. However, the thickness h1 of the first side wall SW1 may increase nonlinearly from the inner side to the outer side of the upper ring 101 without being limited thereto.

The second side wall SW2 may form a second angle a2 with the upper surface of the lower ring 102. When the second angle a2 is 90 degrees, the second side wall SW2 may form a right angle with the upper surface of the lower ring 102. The thickness h2 of the second side wall SW2 may be constant. Although not illustrated in FIG. 4, the thickness h2 of the second side wall SW2 may increase from the outer side toward the inner side of the upper ring 101 when the second angle a2 is an acute angle other than 90 degrees.

In other words, the second side wall SW2 is shown to form a right angle with the upper surface of the lower ring 102 as shown in FIG. 4. However, the thickness h2 of the second side wall SW2 may increase from the outer side to the inner side of the upper ring 101 without being limited thereto.

The second angle a2 may be greater than the first angle a1. For example, since the second angle a2 is a right angle, it may be greater than the first angle a1 which is an acute angle.

The first extension surface 171 may connect the uppermost end of the first side wall SW1 and the uppermost end of the second side wall SW2. For example, the first extension surface 171 comes into contact with the uppermost end of the first side wall SW1 and the uppermost end of the second side wall SW2 and connect them to each other, and may be parallel to the upper surface of the lower ring 102.

The lower ring 102 includes a first loading portion 110 and a second loading portion 120.

The first loading portion 110 may be a part of the upper surface of the lower ring 102. More specifically, the first loading portion 110 may be a portion that connects the upper end of the inner side wall of the lower ring 102 and the lower end of the first side wall SW1, and exists inside the upper surface of the lower ring 102.

The second loading portion 120 may be a part of the upper surface of the lower ring 102. More specifically, the second loading portion 120 may be a portion that connects the upper end of the outer side wall of the lower ring 102 and the lower end of the second side wall SW2, and exists outside the upper surface of the lower ring 102.

An edge ring 200 may be seated on the upper surface of the lower ring 102. For example, the edge ring 200 is seated on the first loading portion 110, and the second edge ring extension surface 207 and the first loading portion 110 may be in contact with each other.

The thickness may mean a thickness in the third direction Z herein. For example, in FIG. 4, the thickness of the first side wall SW1 may refer to a vertical distance from the upper end at an arbitrary point of the first side wall SW1 to the upper surface of the lower ring 102.

In this specification, the inner side may refer to a portion in which a straight distance is closer from the ring-shaped central axis CP, and the outer side may refer to a portion in which the straight distance is farther from the ring-shaped central axis CP. For example, the inner side of the lower ring 102 of FIG. 4 may be a portion having the lower ring inner diameter L2. Also, the outer side of the lower ring 102 of FIG. 4 may be a portion having the lower ring outer diameter L1.

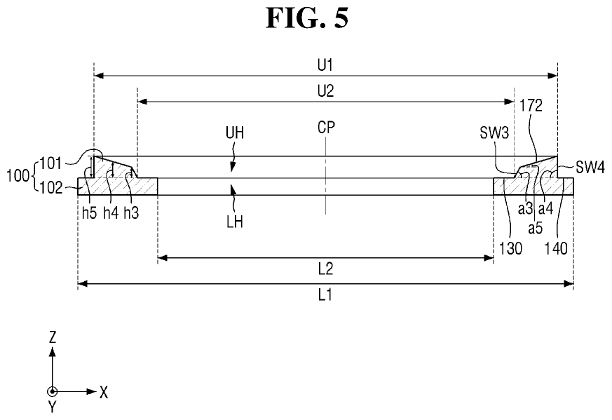

FIG. 5 is a cross-sectional view of the edge covering 100 according to some embodiments of the present disclosure. For convenience of explanation, points different from those explained using FIGS. 3 and 4 will be mainly explained.

Referring to FIG. 5, the edge covering 100 may be separated into the upper ring 101 and the lower ring 102. However, the edge covering 100 is separated into the upper ring 101 and the lower ring 102 for convenience of explanation, and the edge covering 100 may be a structure in which the upper ring 101 and the lower ring 102 are integrally formed.

The third side wall SW3 may form a third angle a3 with the upper surface of the lower ring 102, and the third angle a3 may be an acute angle. That is, the thickness h3 of the third side wall SW3 may increase from the inner side to the outer side of the upper ring 101.

In FIG. 5, the third side wall SW3 is shown to linearly increase in thickness from the inner side to the outer side of upper ring 101. That is, the extent to which the thickness h3 of the third side wall SW3 increases from the inner side to the outer side of the upper ring 101 is constant, and the third side wall SW3 is shown linearly. However, the thickness h3 of the third side wall SW3 may increase nonlinearly from the inner side to the outer side of the upper ring 101, without being limited thereto.

The fourth side wall SW4 may form a fourth angle a4 with the upper surface of the lower ring 102. When the fourth angle a4 is 90 degrees, the fourth side wall SW4 may form a right angle with the upper surface of the lower ring 102. The thickness h4 of the fourth side wall SW4 may be constant. Although not illustrated in FIG. 5, the thickness h4 of the fourth side wall SW4 may increase from the outer side to the inner side of the upper ring 101 when the fourth angle a4 is an acute angle other than 90 degrees.

In other words, the fourth side wall SW4 is shown to form a right angle with the upper surface of the lower ring 102 as shown in FIG. 5. However, the thickness h4 of the fourth side wall SW4 may increase from the outer side to the inner side of the upper ring 101, without being limited thereto.

The fourth angle a4 may be greater than the third angle a3. For example, since the fourth angle a4 is a right angle, it may be greater than the third angle a3 which is an acute angle.

The second extension 172 may connect the uppermost end of the third side wall SW3 and the uppermost end of the fourth side wall SW4. For example, the second extension 172 comes into contact with the uppermost end of the third side wall SW3 and the uppermost end of the fourth side wall SW4 and connects them to each other, but may not be parallel to the upper surface of the lower ring 102.

The second extension 172 may form a fifth angle a5 with the upper surface of the lower ring 102. That is, the thickness h5 of the second extension 172 may increase from the inner side to the outer side of the upper ring 101.

In FIG. 5 the second extension 172 is shown to linearly increase in thickness from the inner side to the outer side of the upper ring 101. That is, the extent to which the thickness h5 of the second extension 172 increases from the inner side to the outer side of the upper ring 101 is constant, and the second extension 172 is shown linearly. However, the thickness h5 of the second extension 172 may increase nonlinearly from the inner side to the outer side of the upper ring 101, without being limited thereto.

The fifth angle a5 may be smaller than the fourth angle a4 and may be an acute angle. That is, the thickness h5 of the second extension 172 may increase from the inner side to the outer side of the upper ring 101.

The lower ring 102 may include a third loading portion 130 and a fourth loading portion 140. The third loading portion 130 may correspond to the first loading portion 110 of FIGS. 3 and 4. The fourth loading portion 140 may correspond to the second loading portion 120 of FIGS. 3 and 4.

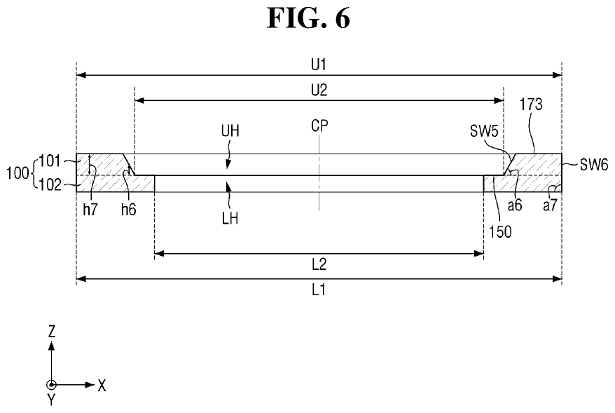

FIG. 6 is a cross-sectional view of the edge covering 100 according to some embodiments of the present disclosure. For convenience of explanation, points different from those explained using FIGS. 3 and 4 will be mainly explained.

Referring to FIG. 6, the edge covering 100 may be separated into the upper ring 101 and the lower ring 102. However, the edge covering 100 is separated into the upper ring 101 and the lower ring 102 for convenience of explanation, and the edge covering 100 may be a structure in which the upper ring 101 and the lower ring are integrally formed.

The fifth side wall SW5 may form a sixth angle a6 with the upper surface of the lower ring 102, and the sixth angle a6 may be an acute angle. That is, the thickness h6 of the fifth side wall SW5 may increase from the inner side to the outer side of the upper ring 101.

In FIG. 6, the thickness h6 of the fifth side wall SW5 is shown to linearly increase from the inner side to the outer side of the upper ring 101. That is, the extent to which the thickness h6 of the fifth side wall SW5 increases from the inner side to the outer side of the upper ring 101 is constant, and the fifth side wall SW5 is shown linearly. However, the thickness h6 of the fifth side wall SW5 may increase nonlinearly from the inner side to the outer side of the upper ring 101, without being limited thereto.

The sixth side wall SW6 may form a seventh angle a7 with the upper surface of the lower ring 102. When the seventh angle a7 is 90 degrees, the sixth side wall SW6 may form a right angle with the upper surface of the lower ring 102. The thickness h7 of the sixth side wall SW6 may be constant. Although no illustrated in FIG. 6, the thickness h7 of the sixth side wall SW6 may increase from the outer side to the inner side of the upper ring 101 when the seventh angle a7 is an acute angle other than 90 degrees.

In other words, the sixth side wall SW6 is shown to form a right angle with the upper surface of lower ring 102 as shown in FIG. 6. However, the thickness h7 of the sixth side wall SW6 may increase from the outer side to the inner side of the upper ring 101, without being limited thereto.

The seventh angle a7 may be greater than the sixth angle a6. For example, since the seventh angle a7 is a right angle, it may be greater than the sixth angle a6 which is an acute angle.

The third extension 173 comes into the uppermost end of the fifth side wall SW5 and the uppermost end of the sixth side wall SW6 and connects them to each other, and may be parallel to the upper surface of the lower ring 102.

The sixth side wall SW6 may be the outer side wall of the edge covering 100. More specifically, the outer side wall of the upper ring 101 may be a part of the sixth side wall SW6. Also, the outer side wall of the lower ring 102 may be the rest of the sixth side wall SW6. Therefore, the outer side wall of the edge covering 100 is the sixth side wall SW6, which may have a flat structure without tilting or bending.

The lower ring 102 may include a fifth loading portion 150. The fifth loading portion 150 may correspond to the first loading portion 110 of FIGS. 3 and 4.

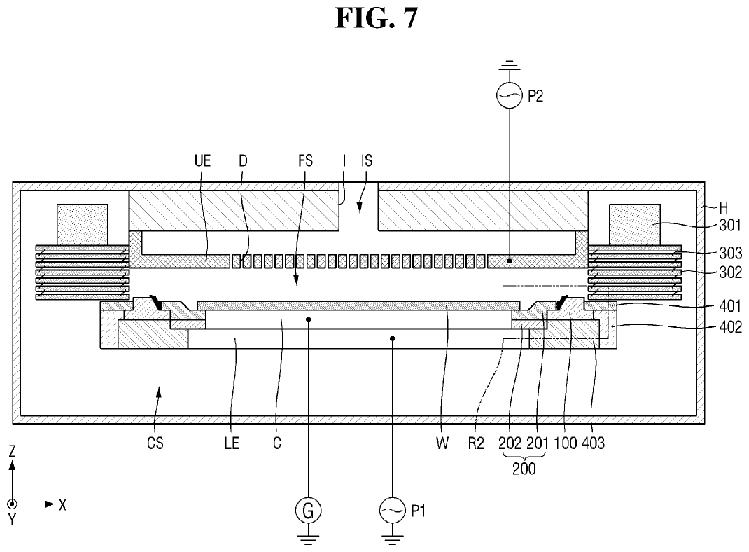

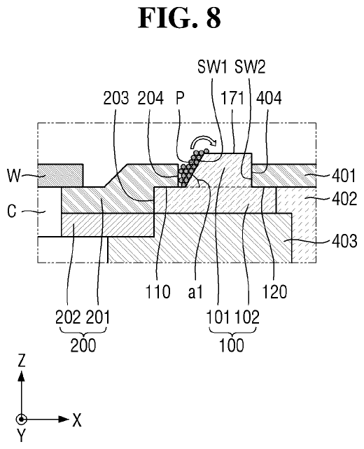

FIG. 7 is a cross-sectional view showing a semiconductor manufacturing device with a wafer seated thereon according to some embodiments of the present disclosure. FIG. 8 is an enlarged view of a portion R2 of FIG. 7. For convenience of explanation, the points different from those explained using FIGS. 1 and 2 will be mainly explained.

Referring to FIGS. 7 and 8, a wafer W is chucked to the upper surface of the electrostatic chuck C and polymer (P) is accumulated during the etching process.

When a carbon (C)-based gas is used as the etching gas, the polymer (P) having a chemical formula CₓF_{y} may be generated around the wafer W. Since the ions are incident perpendicularly to the substrate during the etching process, a relatively large amount of the polymer (P) may be removed from the upper surface of the wafer W by such ions. However, since the ions are hardly incident on the side surfaces of the wafer W, polymer (P) may be accumulated.

The edge ring 200 that surrounds the periphery of the wafer W may be made of Si material and thus has a relatively high thermal conductivity. Therefore, because the thermal energy generated during the plasma process may be received relatively easily, a relatively high temperature may be maintained. On the other hand, the edge covering 100 that surrounds the edge ring 200 may be made of a quartz material and thus has a relatively low thermal conductivity. Therefore, because the heat energy generated during the plasma process is less likely to be transferred, a relatively low temperature may be maintained.

In the case of polymer (P), there is a feature in which it is hard to be adsorbed to substances with high temperatures, and is easily adsorbed to substances with low temperatures. Therefore, although the polymer (P) may be accumulated on the side surface of the wafer W, the polymer (P) is hard to be accumulated on the edge ring 200 and a large amount of the polymer (P) may be accumulated on the edge covering 100.

Furthermore, a trench may occur in the space between the edge ring 200 and the edge covering 100, which may be regarded as a boundary between the edge ring 200 and the edge covering 100, due to the difference in level and inclination between the edge ring 200 and the edge covering 100. More specifically, due to the difference in thickness between the edge covering 100 and the edge ring 200 and the difference in inclination between the edge ring protrusion 204 and the first side wall SW1, a trench may occur in the space between the edge ring 200 and the edge covering ring 100. Therefore, when the polymer (P) enters the trench, it is not easy to exit the trench.

As a result, a large amount of polymer (P) may be accumulated in the space between the edge ring 200 and the edge covering 100, that is, between the edge ring protrusion 204 and the first side wall SW1.

As explained above, the first side wall SW1 may have the first angle a1 with the upper surface of the lower ring 102. Also, the polymer (P) may move from the plasma formation space FS to the chamber inner space CS due to the influence of the vacuum pump.

The plurality of polymers (P) may be adsorbed onto the surface of the first side wall SW1, and the polymers (P) not adsorbed onto the surface of the first side wall SW1 may be accumulated on the surface of the first side wall SW1 in an unfixed state. The unfixed polymers (P) may move in a direction of an arrow of FIG. 8 along the inclination of the first side wall SW1 having the first angle a1. In other words, the polymer (P) may move from the inner side to the outer side of the edge covering 100.

Assuming that the first angle a1 is an obtuse angle, the polymer (P) may move from the outer side to the inner side of the edge covering 100 when moving along the inclination of the first side wall SW1. Therefore, the polymer (P) is more likely to reach the wafer W, and the wafer W located inside the edge covering 100 may be more likely to be contaminated with the polymer (P).

In all embodiments of the present disclosure, since the first angle a1 is an acute angle, the polymer (P) may move to the outer side of the edge covering 100 along the inclination of the first side wall SW1. Therefore, the edge covering 100 is less likely to reach wafer W, and the wafer W positioned inside the edge covering 100 may be less likely to be contaminated with polymer (P).

In concluding the detailed description, those skilled in the art will appreciate that many variations and modifications may be made to the preferred embodiments without substantially departing from the principles of the present inventive concept. Therefore, the disclosed preferred embodiments of the invention are used in a generic and descriptive sense only and not for purposes of limitation.

What is claimed is:

1. An edge covering comprising:
a lower ring including a first hole; and
an upper ring on the lower ring, wherein the upper ring includes a second hole that overlaps the first hole,
wherein an edge ring is seated on an upper surface of the lower ring, and
the upper ring includes a first side wall that faces the second hole and forms a first angle with the upper surface of the lower ring, the first angle being an acute angle.

2. The edge covering of claim 1,
wherein the upper ring further comprises a second side wall that forms a second angle with the upper surface of the lower ring, the second angle being greater than the first angle.

3. The edge covering of claim 2,
wherein the upper ring further comprises an edge ring extension surface connecting an upper end of the first side wall and an upper end of the second side wall.

4. The edge covering of claim 3,
wherein the edge ring extension surface is parallel to the upper surface of the lower ring.

5. The edge covering of claim 3,
wherein the edge ring extension surface forms a third angle with the upper surface of the lower ring, and the third angle is smaller than the first angle and an acute angle.

6. The edge covering of claim 1,
wherein the edge ring is separable into a first edge ring member and a second edge ring member along a plane parallel to a lower surface of the lower ring, and
the first edge ring member is detachable from the upper surface of the second edge ring member.

7. The edge covering of claim 1,
wherein the lower surface of the lower ring faces the coupler.

8. An edge covering comprising:
a lower ring which includes a first hole having a lower ring inner diameter; and
an upper ring which includes a second hole having an upper ring inner diameter,
wherein an edge ring is seated on an upper surface of the lower ring, and
the upper ring includes a first side wall that faces the second hole and increases in thickness from an inner side to an outer side of the upper ring.

9. The edge covering of claim 8,
wherein the thickness of the first side wall increases linearly from the inner side to the outer side of the upper ring.

10. The edge covering of claim 9,
wherein the upper ring further comprises a second side wall that increases in thickness from an inner side to an outer side of the upper ring.

11. The edge covering of claim 10,
wherein the thickness of the second side wall increases linearly from the inner side to the outer side of the upper ring, and
a linear increase in the thickness of the second side wall is greater than a linear increase in the thickness of the first side wall.

12. The edge covering of claim 10,
wherein the upper ring further comprises an edge ring extension surface connecting an uppermost end of the first side wall and an uppermost end of the second side wall.

13. The edge covering of claim 12,
wherein the edge ring extension surface is parallel to the upper surface of the lower ring.

14. The edge covering of claim 12,
wherein the thickness of the edge ring extension surface increases linearly from the inner side to the outer side of the upper ring, and
a linear increase in the thickness of the first side wall is greater than a linear increase in the thickness of the edge ring extension surface.

15. The edge covering of claim 8,
wherein the edge ring is separable into a first edge ring member and a second edge ring member along a plane parallel to a lower surface of the lower ring, and
the first edge ring member is detachable from an upper surface of the second edge ring member.

16. The edge covering of claim 8,
wherein the lower surface of the lower ring faces the coupler.

17. A semiconductor manufacturing device comprising:
an edge covering;
an edge ring that is seated on an inner side of the edge covering;
an electrostatic chuck which faces the inner side of the edge covering and on which a substrate is loadable; and
an upper electrode and a lower electrode spaced apart from each other with an electrostatic chuck interposed therebetween,
wherein the edge covering includes:
a lower ring including a first hole, and
an upper ring which is installed on the lower ring and includes a second hole that overlaps the first hole,
wherein the edge ring is seated on an upper surface of the lower ring, and
the upper ring includes a first side wall that faces the second hole and forms a first angle with the upper surface of the lower ring, the first angle being an acute angle.

18. The semiconductor manufacturing device of claim 17,
wherein the upper ring further comprises:
a second side wall that forms a second angle with the upper surface of the lower ring, the second angle being greater than the first angle; and
an edge ring extension surface which connects an end of the first side wall and an end of a second sidewall.

19. The semiconductor manufacturing device of claim 18,
wherein the edge ring extension surface is parallel to the upper surface of the lower ring.

20. The semiconductor manufacturing device of claim 18,
wherein the edge ring extension surface forms a third angle with the upper surface of the lower ring, and the third angle is smaller than the first angle and an acute angle.
